(19) United States
(12) Patent Application Publication
(10) Pub. No.: US 2006/0030111 A1
(43) Pub. Date: Feb. 9, 2006

(54) Method of manufacturing semiconductor device

(76) Inventors: Satoshi Onai, Gunma (JP); Shinobu Teranaka, Gifu (JP)

Correspondence Address: FISH & RICHARDSON P.C., P.O. BOX 1022, MINNEAPOLIS, MN, 55440-1022, US

(21) Appl. No.: 11/184,213

(22) Filed: Jul. 18, 2005

(30) Foreign Application Priority Data
Aug. 6, 2004 (JP) P2004-230171

(51) Int. Cl. H01L 21/336

(52) U.S. Cl. 438/296; 438/337; 438/345; 438/309

(57) ABSTRACT

There has heretofore been a problem that desired withstanding characteristics cannot be obtained since a buried diffusion layer climbs up more than necessary in other heat treatment steps. In the present invention, after an N-type buried diffusion layer is formed, dry etching is performed in order to round off corner portions of a groove used for inter-element isolation and the like. Moreover, the groove is filled up with an NSG film formed by use of a CVD method, for example. Furthermore, a trench forming an isolation region is filled up with a HTO film and a polycrystalline silicon film, which are formed by use of the CVD method, for example. By use of the manufacturing method described above, it is possible to realize a semiconductor device capable of obtaining desired withstanding characteristics by preventing the N-type buried diffusion layer from climbing up more than necessary.

### BACKGROUND OF THE INVENTION

1. Field of the Invention

The present invention relates to a technology of reducing a heat treatment step where a thermal oxidation method is used, suppressing an diffusion extent of a buried diffusion layer, and improving high-frequency characteristics.

2. Description of the Related Art

In a conventional method of manufacturing a semiconductor device, an N-type epitaxial layer is formed on a P-type semiconductor substrate. In this event, an N-type buried diffusion layer is formed on the substrate and the epitaxial layer. Thereafter, in a desired region of the epitaxial layer, a LOCOS (local oxidation of silicon) oxide film is formed by steam oxidation at about 1000° C. Subsequently, a trench is dug into the LOCOS oxide film, and the trench is filled with a thermal oxide film and polysilicon. Thus, the trench is used as an isolation region. This technology is described for instance in Japanese Patent Application Publication No. Hei 10 (1998)-303209.

In a conventional method of manufacturing a semiconductor device, there is a technology of realizing planarity and miniaturization of a surface of a semiconductor layer by use of a STI (shallow trench isolation) method instead of a LOCOS method. In the STI method, a groove formed by dry etching is filled with an insulating film, and a trench is formed from an upper surface of the insulating film. Thereafter, a thermal oxide film is formed on an inner wall of the trench, and by use of a CVD (chemical vapor deposition) method, the trench is filled with a CVD oxide film. This technology is described for instance in Japanese Patent Application Publication No. Hei 9 (1997)-8119.

As described above, in the conventional method of manufacturing a semiconductor device, when the LOCOS oxide film is formed on the epitaxial layer, first, a silicon nitride film is selectively formed on the epitaxial layer, the silicon nitride film which has an opening provided in a region where the LOCOS oxide film is formed. Thereafter, steam oxidation at about 1000° C., for example, is performed to form the LOCOS oxide film. Specifically, since the substrate itself is placed in a heat environment of about 1000° C. in formation of the LOCOS oxide film, the buried diffusion layer already formed on the epitaxial layer is made diffused more than necessary.

Particularly, the buried diffusion layer formed for the purpose of reducing a resistance value in a collector region is caused to climb up or down more than necessary if it is put in the above heat environment. Due to the climbing-up of the buried diffusion layer, a lengthwise distance from a bottom level of a base region to an upper surface level of the collector region is shortened. Accordingly, there arises a problem that desired withstanding characteristics cannot be obtained. Moreover, in order to secure a desired withstanding, it is possible to cope with the upward swelling of the buried diffusion layer by thickening the epitaxial layer and forming the buried diffusion layer in a deep portion. However, the epitaxial layer is accordingly formed to be thicker than necessary, which leads to a problem of an increased process load. Furthermore, by forming the epitaxial layer to be thick, the resistance value in the collector region is increased. Thus, there arises a problem that high-frequency characteristics are deteriorated.

After a groove and a trench are formed from the surface of the epitaxial layer, etching damages of the groove and the trench, and the like are removed. Moreover, upper and lower edge portions of the groove are removed. In this event, after a thermal oxide film is formed in the groove and the trench by use of a thermal oxidation method, the thermal oxide film is removed. Furthermore, an oxide film covering an inner wall of the trench is formed by use of the thermal oxidation method. Specifically, since the thermal oxidation method is used, the substrate itself is placed in the heat environment. Thus, as described above, problems similar to those described above are caused by the climbing-up or climbing-down of the buried diffusion layer. Moreover, in formation of the groove and the trench, the use of the thermal oxidation method causes a bird's beak to occur from an upper edge portion of the groove. Thus, there arises a problem that a size of an active region is changed.

Moreover, if the buried diffusion layer in the collector region is diffused more than necessary as described above, short-circuiting between adjacent elements occurs. In order to prevent the short-circuiting, it is required to form the trench to be deep, the trench forming the isolation region. Thus, there arises a problem that the process load and manufacturing costs are increased by formation of the trench. Moreover, in order to maintain desired withstanding characteristics as a semiconductor element, it is required to form the epitaxial layer with high thickness. Thus, there arises a problem that formation of the trench brings about increases in the process load and the manufacturing cost.

### SUMMARY OF THE INVENTION

The present invention was made in consideration for the foregoing circumstances. A method of manufacturing a semiconductor device of the present invention includes the steps of forming a groove in a semiconductor layer having a collector buried diffusion layer formed thereon, and removing, by etching, at least the semiconductor layer positioned in upper edge portions of the groove; filling the groove with a first insulating film by use of a vapor phase growth method, forming a trench from a surface of the first insulating film, filling the trench with a second insulating film by use of a vapor phase growth method, and polishing the first and second insulating films; and forming a collector diffusion layer, a base diffusion layer and an emitter diffusion layer from a surface of the semiconductor layer. Therefore, in the present invention, after the collector buried diffusion layer is formed, a step of using a thermal oxidation method can be significantly reduced. Moreover, the collector buried diffusion layer can be prevented from climbing up or down more than necessary. Furthermore, by etching and removing the semiconductor layer positioned in the upper edge portions of the groove, a thermal stress applied to the semiconductor layer therein and electric field concentration are eased. Thus, occurrence of a crystal defect in the semiconductor layer in a lower edge portion can be reduced.

The method of manufacturing a semiconductor device of the present invention further includes, after the polishing step, the step of forming a third insulating film by use of the vapor phase growth method after selectively removing the third insulating film in order that it should cover at least an upper surface of a boundary region between the first insulating film buried in the groove and the semiconductor layer, and forming a silicon film on the semiconductor layer. Therefore, in the present invention, the third insulating film is formed on the semiconductor layer in order that edge portions of the surface of the semiconductor layer having the groove formed therein and a base extraction electrode should not come into direct contact with each other. Thus, a thermal stress applied to the semiconductor layer and electric field concentration are eased. Moreover, occurrence of a crystal defect in the semiconductor layer is reduced. Furthermore, even if the crystal defect occurs in the semiconductor layer, a junction leak current between a collector and a base can be reduced by separating the crystal defect from a passage of a base current.

The method of manufacturing a semiconductor device of the present invention further includes the step of selectively removing the silicon film, forming the base extraction electrode, forming a fourth insulating film on the semiconductor layer by use of the vapor phase growth method, forming an opening in the fourth insulating film, and forming a cobalt silicide film on the silicon film exposed from the opening. Therefore, in the present invention, by forming the cobalt silicide film on the base extraction electrode, a connection resistance and a parasitic resistance in the base extraction electrode can be reduced.

The method of manufacturing a semiconductor device of the present invention further includes the step of forming a contact hole in a fifth insulating film by using the cobalt silicide film as a stopper film, the fifth insulating film which is formed on an upper surface of the silicon film. Therefore, in the present invention, when the contact hole is formed on the base extraction electrode, the cobalt silicide film can be used as an etching stopper film.

The method of the present invention includes the step of etching and removing the semiconductor layer at least in the upper edge portions of the groove after the groove is formed from the surface of the semiconductor layer. The step described above makes it possible to realize a structure in which a crystal defect hardly occurs in the semiconductor layer even in a heat treatment step such as deposition of an insulating film after the groove is formed. Moreover, by performing the step by etching instead of by using the thermal oxidation method, climbing-up and climbing-down of the collector buried diffusion layer can be suppressed.

Moreover, in the present invention, the groove is filled with an insulating film deposited by use of a CVD method. Furthermore, the trench forming an isolation region is filled with an insulating film deposited by use of the CVD method. By these steps, the upward or downward swelling of the collector buried diffusion layer can be suppressed.

Furthermore, in the present invention, the cobalt silicide film is formed on the base extraction electrode. The base extraction electrode is connected through the cobalt silicide film to a metal layer buried in the contact hole. Thus, it is possible to reduce the connection resistance and the parasitic resistance in the base extraction electrode.

Furthermore, in the present invention, the cobalt silicide film is formed on the base extraction electrode exposed from an opening of an insulating film deposited on the base extraction-electrode. Thus, when the contact hole is formed on the base extraction electrode, the cobalt silicide film can be used as the etching stopper film.

### BRIEF DESCRIPTION OF THE DRAWINGS

FIG. 1 is a cross-sectional view showing a method of manufacturing a semiconductor device according to an embodiment of the invention.

FIG. 2 is a cross-sectional view showing the method of manufacturing a semiconductor device according to the embodiment of the invention.

FIG. 3 is a cross-sectional view showing the method of manufacturing a semiconductor device according to the embodiment of the invention.

FIG. 4 is a cross-sectional view showing the method of manufacturing a semiconductor device according to the embodiment of the invention.

FIG. 5 is a cross-sectional view showing the method of manufacturing a semiconductor device according to the embodiment of the invention.

FIG. 6 is a cross-sectional view showing the method of manufacturing a semiconductor device according to the embodiment of the invention.

FIG. 7 is a cross-sectional view showing the method of manufacturing a semiconductor device according to the embodiment of the invention.

FIG. 8 is a cross-sectional view showing the method of manufacturing a semiconductor device according to the embodiment of the invention.

FIG. 9 is a cross-sectional view showing the method of manufacturing a semiconductor device according to the embodiment of the invention.

FIG. 10 is a cross-sectional view showing the method of manufacturing a semiconductor device according to the embodiment of the invention.

FIG. 11 is a cross-sectional view showing the method of manufacturing a semiconductor device according to the embodiment of the invention.

FIG. 12 is a cross-sectional view showing the method of manufacturing a semiconductor device according to the embodiment of the invention.

### DESCRIPTION OF THE PREFERRED EMBODIMENT

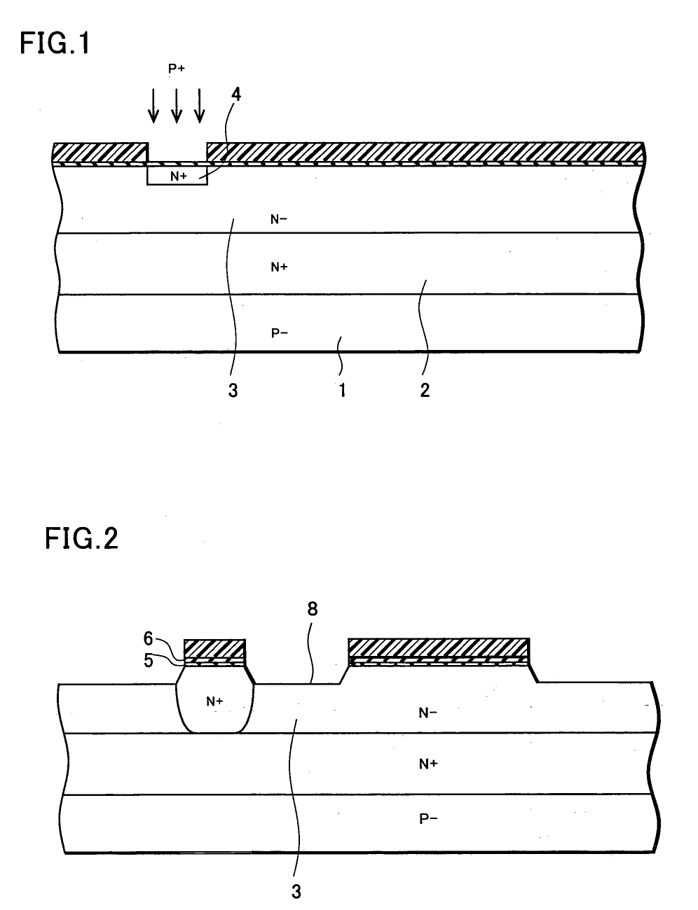

With reference to FIGS. 1 to 12, a method of manufacturing a semiconductor device according to a preferred embodiment of the invention will be described in detail below.

FIGS. 1 to 12 are cross-sectional views showing the method of manufacturing a semiconductor device according to this embodiment. Note that, although a case where an NPN-type transistor, for example, is formed in one of element formation regions separated by isolation regions will be described in the following description, the embodiment of the present invention is not limited to this case. For example, a semiconductor integrated circuit device may be formed by forming an N-channel MOS transistor, a P-channel MOS transistor, a vertical PNP transistor and the like in the other element formation regions.

First, as shown in FIG. 1, a P-type single crystal silicon substrate 1 is prepared. By use of a heretofore known photolithography technology, an N-type buried diffusion layer 2 is formed on a surface of the substrate 1. Thereafter, the substrate 1 is placed on a susceptor of an epitaxial growth apparatus. Subsequently, a high temperature such as 1200° C. is provided to the substrate 1 by lamp heating, and simultaneously, SiHCl3 gas and H2 gas are introduced into a reaction tube. Thus, an epitaxial layer 3 having a specific resistance of 0.1 to 2.0 Ω·cm and a thickness of about 0.5 to 1.5 μm is grown on the substrate 1. Thereafter, a silicon oxide film is formed on the epitaxial layer 3. Note that the N-type buried diffusion layer 2 in this embodiment corresponds to a “collector buried diffusion layer” of the present invention.

By use of the heretofore known photolithography technology, a photoresist is formed as a selective mask, the photoresist having an opening provided in a portion where an N-type diffusion region 4 is to be formed. Thereafter, ion implantation of an N-type impurity, such as phosphorus (P), is performed by an introduction amount of 1.0×10¹⁴ to 1.0×10¹⁶/cm² at an acceleration voltage of 80 to 120 keV. Subsequently, the photoresist is removed, and the ion-implanted impurity is diffused.

Note that the substrate 1 and the epitaxial layer 3 in this embodiment correspond to a “semiconductor layer” of the present invention. Although a case where one epitaxial layer 3 is formed on the substrate 1 is described in this embodiment, the present invention is not limited to this case. For example, the “semiconductor layer” of the present invention may include: only a substrate; or a substrate and a plurality of epitaxial layers laminated on the substrate. Moreover, the substrate may be an N-type single crystal silicon substrate or a compound semiconductor substrate.

Next, as shown in FIG. 2, a silicon oxide film 5 is formed on the epitaxial layer 3, and a silicon nitride film 6 is formed on the silicon oxide film 5. Thereafter, by use of the heretofore known photolithography technology, a photoresist is formed as a selective mask, the photoresist having an opening provided on a portion where a groove 8 is formed. After the silicon oxide film 5 and the silicon nitride film 6 are removed, about 5000 Å of the epitaxial layer 3 is removed by dry etching. On the epitaxial layer 3, the groove 8 is formed from the surface thereof. Note that the groove 8 in this embodiment corresponds to a “groove” of the present invention. Meanwhile, the “groove” of the present invention may be formed by use of an arbitrary manufacturing method as long as the groove has a concave structure with respect to the surface of the epitaxial layer 3.

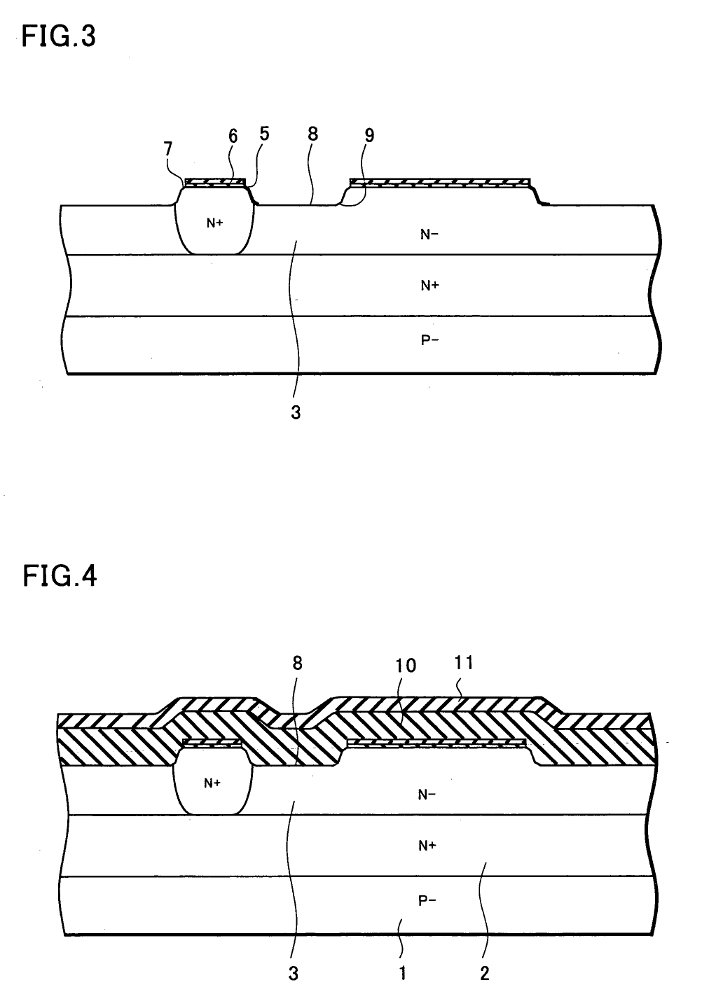

Next, as shown in FIG. 3, after the photoresist is removed, the silicon oxide film 5 and the silicon nitride film 6 are partially removed in order that upper edge portions 7 of the groove 8 should be exposed. Thereafter, isotropic dry etching, for example, is performed by using the silicon nitride film 6 as an etching mask. By this etching step, the epitaxial layer 3 positioned in the upper edge portions 7 and lower edge portions 9 of the groove 8 is removed. Here, the upper and lower edge portions 7 and 9 of the groove 8 have obtuse-angled shapes compared to those before the etching. Practically, the upper and lower edge portions 7 and 9 of the groove 8 have round shapes.

Specifically, in this embodiment, etching is performed instead of a thermal oxidation method, to remove the epitaxial layer 3 positioned in the upper and lower edge portions 7 and 9 of the groove 8. Thus, the N-type buried diffusion layer 2 can be prevented from climbing up and climbing down more than necessary. Note that the thermal oxidation method may be used as long as withstanding characteristics are not affected by the climbing-up of the N-type buried diffusion layer 2. Moreover, through the use of this etching step, it also becomes possible to remove an etching damage caused during formation of the groove 8.

Next, as shown in FIG. 4, by use of a high density plasma CVD (HDP CVD) method, an NSG (non-doped-silicate glass) film 10 is deposited on the epitaxial layer 3. In this event, for example, about 6000 Å of the NSG film 10 is deposited so as to fill up the groove 8.

By use of a low pressure CVD method, an HTO (high temperature oxide) film 11 is deposited on an upper surface of the NSG film 10 under a temperature condition of about 800° C. In this event, the HTO film 11 is deposited with a thickness of 3000 Å to 5000 Å, for example. Moreover, the HTO film 11 is a film having a better step covering property than the NSG film 10. Meanwhile, the NSG film 10 has a better filling property than the HTO film 11, and is used for filling up the groove 8 as described above.

Note that the NSG film 10 and the HTO film 11 in this embodiment correspond to a “first insulating film” of the present invention. The “first insulating film” of the present invention may be a film which fills up the groove 8. Moreover, as the “first insulating film” of the present invention, at least only the NSG film 10 may be used.

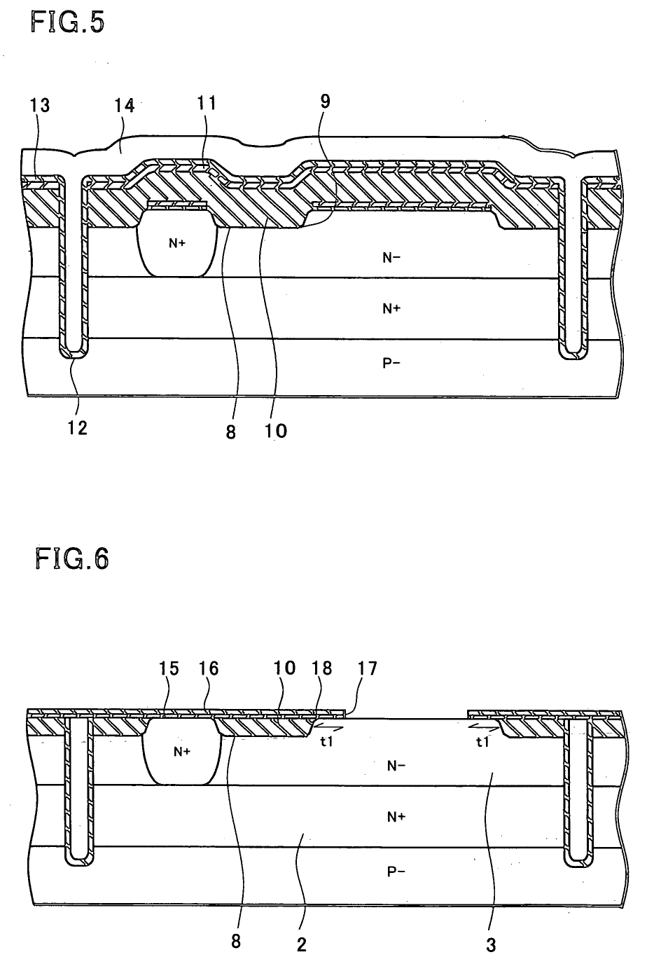

Next, as shown in FIG. 5, by use of the heretofore known photolithography technology, a trench 12 is formed by dry etching from an upper surface of the HTO film 11. Here, the trench 12 is formed so as to have a depth of about 6 μm, for example. Note that, the HTO film 11 is also removed from its surface in the step of forming the trench 12, and the thickness of the HTO film 11 becomes also reduced after forming the trench 12. Here, the reason why the HTO film 11 is deposited with the thickness within the range described above is because a problem of etching failure may occur if the HTO film 11 is thinner than 3000 Å. Meanwhile, if the HTO film 11 is thicker than 5000 Å, it may become difficult to pattern the NSG film 10 and the HTO film 11.

Thereafter, on the inside of the trench 12 and on the HTO film 11, an HTO film 13 is deposited under a temperature condition of about 800° C. by use of the low pressure CVD method. The HTO film 13 is deposited with a thickness of about 3000 Å, and a part of the trench 12 is filled up from an inner wall of the trench 12. Thereafter, on an upper surface of the HTO film 13, a polycrystalline silicon film 14 is deposited by use of a CVD method. The polycrystalline silicon film 14 is deposited with a thickness of about 8000 Å, and inside of the trench 12 is completely filled up with the polycrystalline silicon film 14. In this embodiment, after the HTO film 13 is buried in the trench 12, the polycrystalline silicon film 14 is buried therein. Accordingly, an amount of the polycrystalline silicon film 14 deposited on the epitaxial layer 3 can be reduced. Moreover, in the subsequent step using a CMP method, an amount of the polycrystalline silicon film 14 polished can be reduced, and the time spent for the expensive CMP method can be shortened. Note that the HTO film 13 and the polycrystalline silicon film 14 in this embodiment correspond to a “second insulating film” of the present invention. The “second insulating film” of the present invention may be a film which fills up the trench 12 and serves as an isolation region.

Next, as shown in FIG. 6, by using the CMP method using the silicon nitride film 6 as a stopper film, the NSG film 10, the HTO films 11 and 13, and the polycrystalline silicon film 14 are polished and at least partially removed. By this step, obtained is a structure in which the groove 8 is filled up with the NSG film 10 and the trench 12 is filled up with the HTO film 13 and the polycrystalline silicon film 14. After the silicon nitride film 6 is removed by using phosphoric acid of about 160° C., the silicon oxide film 5 is removed by using buffered hydrogen fluoride (BHF).

Subsequently, after a silicon oxide film 15 is deposited on the epitaxial layer 3 by use of the CVD method, a TEOS (tetra-ethyl-ortho-silicate) film 16 is deposited by use of the CVD method so as to cover the silicon oxide film 15. In this event, although not shown in FIG. 6, a plurality of element formation regions are formed in a manner that they are separated by the isolation regions on the same substrate 1, and a MOS transistor is formed in one of the element formation regions. Moreover, the silicon oxide film 15 is also used as a silicon oxide film formed as a protective film for a gate electrode of the MOS transistor. As described above, the silicon oxide film 15 and the TEOS film 16 are deposited by use of the CVD method. Thus, the N-type buried diffusion layer 2 can be prevented from climbing up and climbing down more than necessary in a heat environment due to the CVD method.

Note that the silicon oxide film 15 is not necessarily limited to the one deposited by use of the CVD method. The silicon oxide film 15 may be formed by use of the thermal oxidation method as long as withstanding characteristics are not affected by climbing-up of the N-type buried diffusion layer 2.

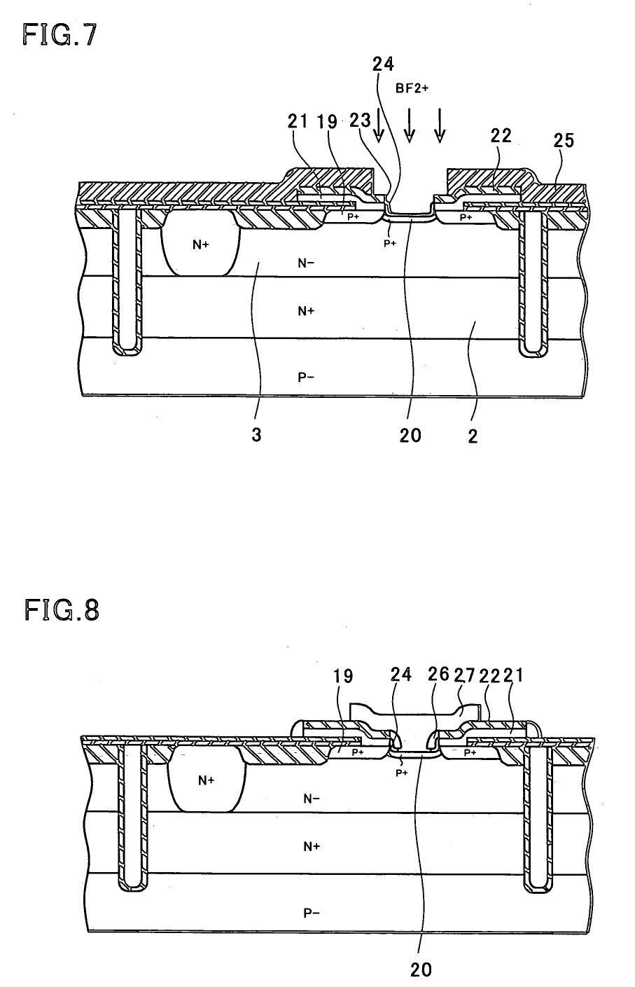

Next, the silicon oxide film 15 and the TEOS film 16 are selectively removed so as to form an opening 17 in formation regions of an external base region 19 (see FIG. 7) and an active base region 20 (see FIG. 7) of an NPN-type transistor. As shown in FIG. 6, the opening 17 is formed to have a fixed distance t1 from upper edge portions 18 of the groove 8. Here, the upper edge portions 18 mean upper edge portions newly formed by etching and removing the upper edge portions 7 of the groove 8 as described above with reference to FIG. 2. Moreover, the upper edge portions 18 mean boundary regions of the epitaxial layer 3 coming in contact with the silicon oxide film 15. By use of the structure described above, a base extraction electrode 21 (see FIG. 7), which is formed on the TEOS film 16, and the upper edge portions 18 of the groove 8 can be prevented from coming into contact with each other. Moreover, even if a crystal defect is caused in the epitaxial layer 3 from the upper edge portions 18 of the groove 8, generation of a leak current between a collector and a base through the crystal defect can be reduced. Note that the silicon oxide film 15 and the TEOS film 16 in this embodiment correspond to a “third insulating film” of the present invention. The “third insulating film” of the present invention may be an insulating film which prevents direct contact between the base extraction electrode 21 (see FIG. 7) and the upper edge portions 18 of the groove 8.

Next, as shown in FIG. 7, an amorphous silicon (a-Si) film is deposited with a thickness of about 2000 Å on an upper surface of the epitaxial layer 3. Thereafter, ion implantation of a P-type impurity, such as boron fluoride (BF2), is performed onto the substantially entire surface thereof. Here, the impurity may have been mixed with a-Si formation gas (gas made of H2 and silicon, such as silane) beforehand, or the impurity may be deposited. Note that, in this embodiment, the a-Si film is used as a diffusion source and is utilized as the base extraction electrode 21. Thus, it is desirable to perform ion implantation capable of accurately controlling a resistance value and a concentration of the external base region 19.

Thereafter, a TEOS film 22 is deposited with a thickness of about 2000 Å by use of a plasma CVD method so as to cover the a-Si film. Here, the TEOS film 22 is deposited at a low temperature in order that conversion of the a-Si film into Poly-Si should be impossible, and therefore, the a-Si film remains in the state of being a-Si until the next etching step is finished. Note that the TEOS film 22 in this embodiment corresponds to a “fourth insulating film” of the present invention. The “fourth insulating film” of the present invention may be a film which insulates the base extraction electrode 21 from an emitter extraction electrode 27 (see FIG. 8).

Next, by use of the heretofore known photolithography technology, the a-Si film and the TEOS film 22 are selectively removed by etching so as to form an opening 23 in the formation region of the active base region 20. Accordingly, the patterned a-Si film is utilized as the base extraction electrode 21.

Here, in this embodiment, since the a-Si film is patterned without being converted into Poly-Si, surfaces of the base extraction electrode 21 and the active base region 20 are made smooth. Specifically, since there are no irregularities formed on the surface where the active base region 20 is formed, the active base region 20 has an approximately uniform depth of diffusion throughout the region. Moreover, since there are no irregularities on a sidewall of the base extraction electrode 21, there will be no influence on shapes of a silicon oxide film 24 and a spacer 26 (see FIG. 8), which are grown in the subsequent step.

Next, the silicon oxide film 24 is formed with a thickness of about 100 to 200 Å on the sidewall of the base extraction electrode 21 and on the epitaxial layer 3. Thereafter, the impurity in the base extraction electrode 21 is diffused in the epitaxial layer 3 to form the external base region 19. Moreover, by use of the heretofore known photolithography technology, a photoresist 25 is formed as a selective mask, which has an opening provided over a portion where the active base region 20 is to be formed. Subsequently, through the silicon oxide film 24, ion implantation of a P-type impurity, such as boron fluoride (BF2), is performed by an introduction amount of 1.0×10¹² to 1.0×10¹⁴/cm² at an acceleration voltage of 10 to 30 keV Thereafter, the photoresist 25 is removed, and the ion-implanted impurity is diffused. Here, since a connection region on the surface of the epitaxial layer 3 is maintained to be flat without irregularities, a contact resistance can be reduced.

Next, as shown in FIG. 8, the spacer 26 is formed on the sidewalls of the base extraction electrode 21 and the TEOS film 22, which are corresponding to the active base region 20. In this event, the spacer 26 is formed of an a-Si film or a Poly-Si film by anisotropic etching. Thereafter, the silicon oxide film 24 on the surface of the active base region 20 is removed by wet etching, for example.

On the exposed upper surface of the active base region 20, a silicon film made of Poly-Si or a-Si is deposited. In consideration of a resistance value of the emitter extraction electrode and an impurity concentration in an emitter region, the silicon film is subjected to ion implantation of an N-type impurity, such as arsenic (As), by an introduction amount of 1.0×10¹⁴ to 1.0×10¹⁶/cm² at an acceleration voltage of 80 to 120 keV. Thereafter, by use of the heretofore known photolithography technology, the silicon film is selectively removed by etching to form the emitter extraction electrode 27. Here, the base extraction electrode 21 and the emitter extraction electrode 27 are insulated from each other by the TEOS film 22 and the silicon oxide film 24.

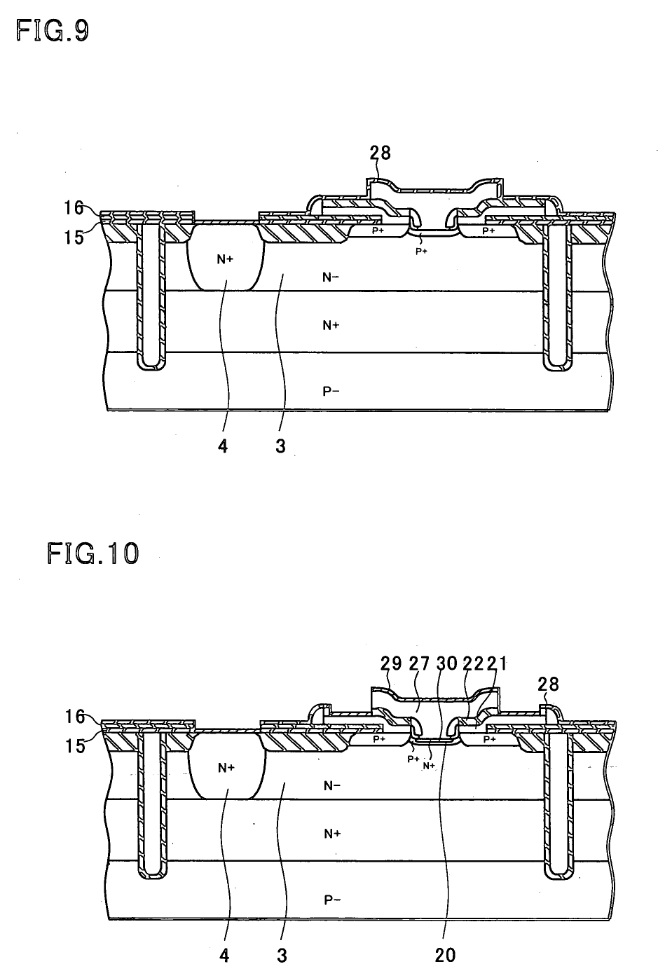

Next, as shown in FIG. 9, a TEOS film 28 is deposited on the epitaxial layer 3 by use of the low pressure CVD method, for example. Thereafter, by use of the heretofore known photolithography technology, the silicon oxide film 15 and the TEOS films 16 and 28 are selectively removed by dry etching so as to expose the N-type diffusion region 4. In this event, etching conditions can be set so as to expose only the N-type diffusion region 4. Thus, the risk of over-etching the surface of the epitaxial layer 3 can be significantly reduced.

Next, as shown in FIG. 10, by use of the heretofore known photolithography technology, the TEOS films 16 and 28 are selectively removed by dry etching so as to expose a part of the base extraction electrode 21. In this event, etching conditions can be set by considering only the thicknesses of the TEOS films 16 and 28 deposited on the base extraction electrode 21. Thus, the risk of over-etching the surface of the base extraction electrode 21 can be significantly reduced.

Thereafter, the TEOS film 28 on the upper and side surfaces of the emitter extraction electrode 27 is removed. Subsequently, a cobalt layer is selectively formed on the exposed upper surfaces of the N-type diffusion region 4, the base extraction electrode 21 and the emitter extraction electrode 27. The cobalt layer is removed after an annealing treatment is conducted. In a heat environment during the annealing treatment, a cobalt silicide (CoSi₂) film 29 is formed on the exposed surfaces of the N-type diffusion region 4, the base extraction electrode 21 and the emitter extraction electrode 27.

Note that, in the heat environment during the annealing treatment with the cobalt layer deposited, the impurity injected into and diffused in the emitter extraction electrode 27 undergoes solid phase diffusion from the emitter extraction electrode 27. Thus, an N-type emitter region 30 is formed on the surface of the active base region 20.

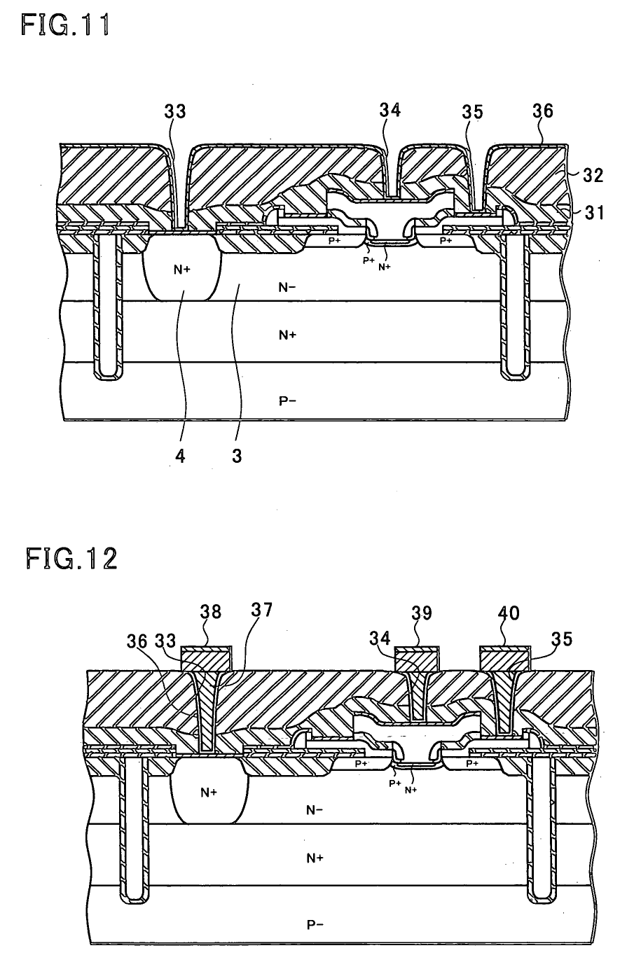

Next, as shown in FIG. 11, a silicon nitride film (not shown) is deposited on the epitaxial layer 3 by use of the CVD method. Thereafter, liquid SOG (spin on glass) is applied to an upper surface of the silicon nitride film to form a SOG film 31. Subsequently, a TEOS film 32 is deposited on the SOG film 31 by use of the low pressure CVD method.

In order to secure a planarity of the surface of the TEOS film 32, etching-back is carried out from the surface side of the substrate 1 by use of the CMP method. Thereafter, by use of the heretofore known photolithography technology, contact holes 33 to 35 are formed through the SOG film 31, the TEOS film 32 and the like by dry etching using CHF₃/O₂ gas, for example.

In this event, as shown in FIG. 11, the contact hole 33 for a collector electrode is the deepest, and the contact holes 33 to 35 are simultaneously formed under etching conditions for forming the contact hole 33. As described above, the cobalt silicide film 29 is formed on the surfaces of the N-type diffusion region 4, the base extraction electrode 21 and the emitter extraction electrode 27. Here, the cobalt silicide film 29 is utilized as an etching stopper film in dry etching. As a result, even if the contact holes 33 to 35 are formed by the same step, particularly, the surfaces of the base extraction electrode 21 and the emitter extraction electrode 27 can be prevented from being over-etched. Thereafter, a barrier metal film 36 is formed on exposed surfaces of the cobalt silicide film 29; sidewalls of the contact holes 33 to 35; and the TEOS film 32.

Note that the silicon nitride film (not shown) in this embodiment corresponds to a “fifth insulating film” of the present invention. The “fifth insulating film” of the present invention may be an insulating film formed on the base extraction electrode 21.

Lastly, as shown in FIG. 12, the contact holes 33 to 35 are filled with a tungsten (W) film 37. Thereafter, by use of the CVD method, an aluminum-copper (AlCu) film and a barrier metal film are deposited on the W film 37 and the barrier metal film 36. Subsequently, by use of the heretofore known photolithography technology, the AlCu film and the barrier metal film are selectively removed to form a collector electrode 38, an emitter electrode 39 and a base electrode 40.

As described above, in this embodiment, after the N-type buried diffusion layer 2 is formed, a high-temperature processing step such as the thermal oxidation method, for example, is reduced. Accordingly, the N-type buried diffusion layer 2 is prevented from climbing up and climbing down more than necessary by a heat treatment in the subsequent step. By use of the manufacturing method described above, the thickness of the epitaxial layer 3 can be reduced. Thus, the process load can be reduced. Moreover, by reducing the thickness of the epitaxial layer 3, the depth of the trench 12 forming the isolation region can be reduced. Thus, the process load can be reduced.

Moreover, the cobalt silicide film 29 formed on the surfaces of the N-type diffusion region 4, the base extraction electrode 21 and the emitter extraction electrode 27 is used as the etching stopper film in formation of the contact holes 33 to 35. Moreover, in consideration of mask misalignment, the cobalt silicide film 29 is formed to be wider than a contact hole region. Particularly in the base extraction electrode 21, since a current also flows in a horizontal direction relative to the substrate 1, resistance reduction can be realized by the cobalt silicide film 29.

Moreover, in the semiconductor device manufactured by use of the manufacturing method described above, even if the thickness of the epitaxial layer 3 is reduced, a lengthwise distance from the bottom level of the base region to the upper surface level of the collector region can be secured. Accordingly, desired withstanding characteristics can be obtained. Furthermore, by reducing the thickness of the epitaxial layer 3, the resistance value in the collector region is lowered. Thus, high-frequency characteristics can also be improved. Meanwhile, by reducing climbing-down of the N-type buried diffusion layer 2, a parasitic capacity between the semiconductor substrate and the collector region is reduced. Thus, the high-frequency characteristics can be maintained.

Note that, in this embodiment, the description was given of the case where the CVD method, for example, is used as the vapor phase growth method. However, the method is not limited to the CVD method. Besides the CVD method, a physical vapor phase growth method such as vapor deposition may be used. Specifically, any method may be used as long as the method can significantly reduce the step of subjecting the semiconductor substrate to a high-temperature heat treatment such as the thermal oxidation method. Moreover, although the description was given of the case where the cobalt silicide film is used as silicide, the embodiment of the present invention is not limited to this case. The effects described above can also be obtained by use of a molybdenum silicide (MoSi₂) film, a tungsten silicide (WSi₂) film, a titanium silicide (TiSi₂) film, a nickel silicide (NiSi₂) film, a platinum silicide (PtSi₂) film or the like in place of the cobalt silicide film. Besides the above, various changes can be made without departing from the scope of the embodiment of the present invention.

What is claimed is:

1. A method of manufacturing a semiconductor device, comprising the steps of
forming a groove in a semiconductor layer having a collector buried diffusion layer formed thereon, and removing by an etching process at least the semiconductor layer positioned in an upper end portion of the groove;
filling the groove with a first insulating film by use of a vapor phase growth method, forming a trench from a surface of the first insulating film, filling the trench with a second insulating film by use of the vapor phase growth method, and polishing the first and second insulating films; and
forming a collector diffusion layer, a base diffusion layer and an emitter diffusion layer from a surface of the semiconductor layer.

2. The method of manufacturing a semiconductor device according to claim 1, further comprising the step of:
forming a third insulating film by use of the vapor phase growth method after the polishing step, selectively removing the third insulating film in a manner that the third insulating film covers at least an upper surface of a boundary region between the first insulating film buried in the groove and the semiconductor layer, and forming a silicon film on the semiconductor layer.

3. The method of manufacturing a semiconductor device according to claim 2, further comprising the step of
selectively removing the silicon film, forming a base extraction electrode, forming a fourth insulating film on the semiconductor layer by use of the vapor phase growth method, forming an opening in the fourth insulating film, and forming a cobalt silicide film on the silicon film exposed from the opening.

4. The method of manufacturing a semiconductor device according to claim 3, further comprising the step of:
forming a contact hole in a fifth insulating film, which is formed on the silicon film, by using the cobalt silicide film as a stopper film.
